(19) United States
(12) Patent Application Publication
(10) Pub. No.: US 2006/0076605 A1
(43) Pub. Date: Apr. 13, 2006

(54) IMPROVED FLASH FORWARD TUNNELING VOLTAGE (FTV) FLASH MEMORY DEVICE

(75) Inventors: Shih-Ming Chen, Hsinchu City (TW); Kuo-Chiang Ting, Hsinchu City (TW); Jen-Shiang Leu, Hsinchu City (TW)

Correspondence Address: DUANE MORRIS, LLP;IP DEPARTMENT, 30 SOUTH 17TH STREET, PHILADELPHIA, PA, 19103-4196, US

(73) Assignee: Taiwan Semiconductor Manufacturing Company, Ltd.

(21) Appl. No.: 11/287,856

(22) Filed: Nov. 28, 2005

Related U.S. Application Data
(63) Continuation-in-part of application No. 10/975,672, filed on Oct. 28, 2004, now Pat. No. 6,995,062.
Application No. 10/975,672 is a continuation of application No. 10/290,644, filed on Nov. 8, 2002, now Pat. No. 6,825,085.

(51) Int. Cl. H01L 29/76

(52) U.S. Cl. 257/314

(57) ABSTRACT

A FLASH memory device comprising a substrate having a gate conductor formed thereover is provided. The gate conductor comprises a gate with a floating gate oxide layer formed thereon, the floating gate oxide layer including respective lateral tip portions, whereby the forward tunneling voltage of the FLASH memory is improved. In one embodiment, the respective tip portions have an average width of greater than or equal to about 250 Å.

### CROSS-REFERENCE TO RELATED APPLICATIONS

This application is a continuation-in-part of copending Application Ser. No. 10/975,672 filed, Oct. 28, 2004, entitled “Method to Improve FLASH Forward Tunneling Voltage (FTV) Performance”, the entirety of which is hereby incorporated by reference herein, which is a continuation of U.S. patent application Ser. No. 10/290,644, filed Nov. 8, 2002, now U.S. Pat. No. 6,825,085, the entirety of which is hereby incorporated by reference herein.

### FIELD OF THE INVENTION

The present invention relates generally to semiconductor fabrication and more specifically to formation of flash memory floating gate oxide.

### BACKGROUND OF THE INVENTION

The most important electrical parameter of Flash memory is Forward Tunneling Voltage (FTV). FTV is a measurement of the ease of erasing the cell by removing the charge from the floating gate (FG) to the control gate (GC). The trap-up rate, i.e. electron (e⁻) trapping in oxide, is also an important electrical parameter.

U.S. Pat. No. 6,031,264 B1 to Chien et al. describes a flash EEPROM process using polyoxide steps.

U.S. Pat. No. 5,879,993 to Chien et al. describes a flash EEPROM process.

U.S. Pat. No. 6,355,527 B1 to Lin et al. describes a flash EEPROM process.

U.S. Pat. No. 6,088,269 to Lambertson and U.S. Pat. No. 6,358,796 B1 to Lin et al. each describe related Flash processes.

### SUMMARY OF THE INVENTION

A FLASH memory device comprising a substrate having a gate conductor formed thereover is provided. The gate conductor comprises a gate with a floating gate oxide layer formed thereon, the floating gate oxide layer including respective lateral tip portions, whereby the forward tunneling voltage of the FLASH memory is improved. In one embodiment, the respective tip portions have an average width of greater than or equal to about 250 Å.

The above and other features of the present invention will be better understood from the following detailed description of the preferred embodiments of the invention that is provided in connection with the accompanying drawings.

### BRIEF DESCRIPTION OF THE DRAWINGS

The present invention will be more clearly understood from the following description taken in conjunction with the accompanying drawings in which like reference numerals designate similar or corresponding elements, regions and portions and in which:

FIGS. 1 to 3 schematically illustrate a preferred embodiment of the present invention;

FIGS. 4 and 5 schematically illustrate further processing of the structure of FIG. 3 in forming a flash memory.

### DETAILED DESCRIPTION OF THE PREFERRED EMBODIMENT

Known to the Inventors—Not to be Considered Prior Art

The following is known to the inventors and is not to be considered to be prior art for the purposes of this invention.

The shape of the floating gate oxide is a key factor in the Forward Tunneling Voltage (FTV) and the trap-up rate of Flash memory. The inventors have discovered that achieving a tip-shape of the floating gate oxide improves the FTV of the Flash memory.

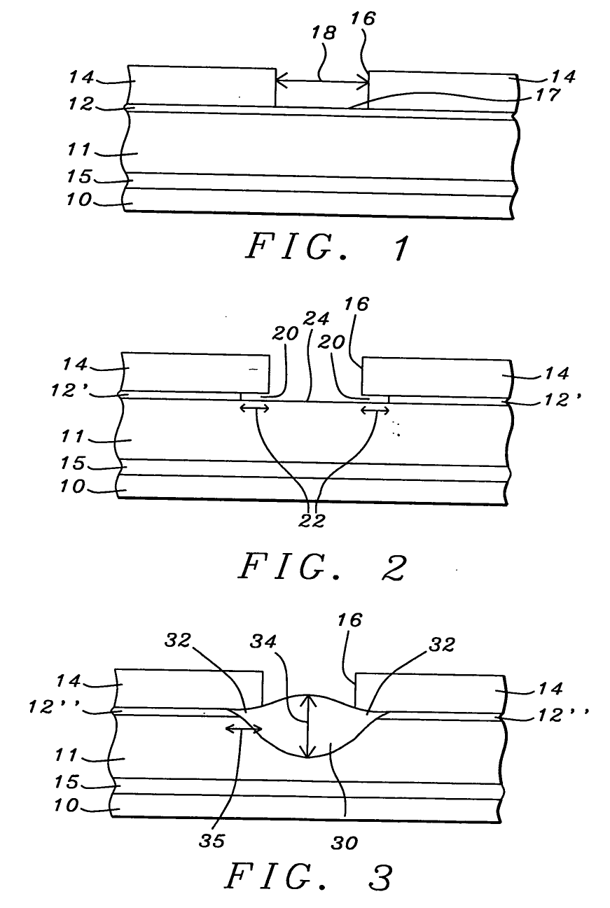

Initial Structure—FIG. 1

As shown in FIG. 1, a structure 10 is provided having an upper gate oxide layer 15 formed thereover.

A polysilicon layer 11 is formed over gate oxide layer 15 to a thickness of preferably from about 900 to 1100 Å, more preferably from about 950 to 1050 Å and most preferably about 1000 Å.

Structure 10 is preferably a silicon substrate or a germanium substrate, is more preferably a silicon substrate and is understood to possibly include a semiconductor wafer or substrate.

A thin silicon oxide layer 12 is then formed over polysilicon layer 11 to a thickness of preferably from about 26 to 34A, more preferably from about 28 to 32A and most preferably about 30A.

A nitride or silicon nitride (Si₃N₄ or just SiN) layer 14 is formed over the thin oxide layer 12 to a thickness of preferably from about 720 to 880 Å, more preferably from about 760 to 840 Å and most preferably about 800 Å.

SiN layer 14 is then patterned preferably using a dry etch process at the following parameters:

temperature: preferably from about 15 to 25° C. and more preferably from about 17 to 23° C.;

pressure: preferably from about 225 to 275 mTorr and more preferably from about 245 to 255 mTorr;

RF power: preferably from about 1000 to 1400 W and more preferably from about 1080 to 1320 W;

O₂ gas flow: preferably from about 4 to 6 sccm and more preferably from about 4.5 to 5.5 sccm;

CF₄ gas flow: preferably from about 66 to 76 sccm and more preferably from about 68 to 74 sccm;

Ar gas flow: preferably from about 750 to 950 sccm and more preferably from about 800 to 900 sccm; and

time: preferably from about 45 to 55 seconds and more preferably from about 48 to 52 seconds.

Patterned SiN layer 14 includes an opening 16 exposing a portion 17 of thin oxide layer 12. Opening 16 has a width 18 corresponding to the critical dimension of the patterning process, preferably from about 0.34 to 0.40 μm and more preferably from about 0.36 to 0.38 μm.

Formation of Undercut 20 in Thin Oxide Layer 12 Under Patterned SiN Layer 14—FIG. 2

As shown in FIG. 2, thin oxide layer 12 is etched to remove the exposed portion 17 of thin oxide layer 12 and to remove a portion of the thin oxide layer 12 adjacent opening 16 under patterned SiN layer 14, forming undercuts 20 and exposing a portion 24 of underlying polysilicon layer 11. Undercuts 20 extend preferably from about 30 to 70 Å under patterned SiN layer 14, more preferably from about 40 to 60 Å and most preferably about 50 Å.

Thin oxide layer 12 is preferably etched to form undercuts 20 using an oxide wet bench dip.

The oxide wet bench is conducted at the following parameters:

HF: H₂O ratio: preferably from about 90:1 to 110:1, more preferably from about 95:1 to 105:1 and most preferably about 100:1;

temperature: preferably from about 18.5 to 28.5° C. and more preferably from about 20.5 to 26.5° C.;

pressure: preferably from about 740 to 780 mTorr and more preferably from about 750 to 770 mTorr; and

time: preferably from about 80 to 100 seconds and more preferably from about 85 to 95 seconds.

Oxidation of The Exposed Portion 24 of Polysilicon Layer 11—FIG. 3

As shown in FIG. 3, the exposed portion 24 of polysilicon layer 11 is oxidized to form floating gate oxide portion 30 having respective tip corners 32 that have a longer and sharper tip profile induced by undercuts 20 than found in conventional methods not having such undercuts 20 formed before the oxidation of polysilicon layer 11. Floating gate oxide portion 30 is essentially indistinguishable from the adjacent etched thin oxide layer 12″ as shown in FIG. 3.

Floating gate oxide portion 30 has a mid-thickness 34 of preferably from about 1000 to 2000 Å and more preferably from about 1400 to 1600 Å. Tip corners 32 each have an average width 35 of preferably from about 250 to 350 Å and more preferably from about 280 to 320 Å. Assuming a critical dimension of 0.37 μm, the ratio of tip width (2 times average width 35) (e.g., 500-700 Å) plus critical dimension to critical dimension is between about 1.13-1.19. Put another way, assuming tip width is defined as “TW” and critical dimension is defined as “CD”, then (2TW+CD)/CD is preferably between about 1.13-1.19. Those in the art will recognize that critical dimensions are dimensions of the smallest geometrical features (width of interconnect line, contacts, trenches, etc.) which can be formed during semiconductor device/circuit (e.g., FLASH memory device) manufacturing using given photolithography technology.

As shown in FIGS. 3-5, the tips corners have top and bottom surfaces, and the top surfaces of tip corners 32 are substantially parallel to the horizontal plane defined by the top surface of the substrate 10 along their average width 35.

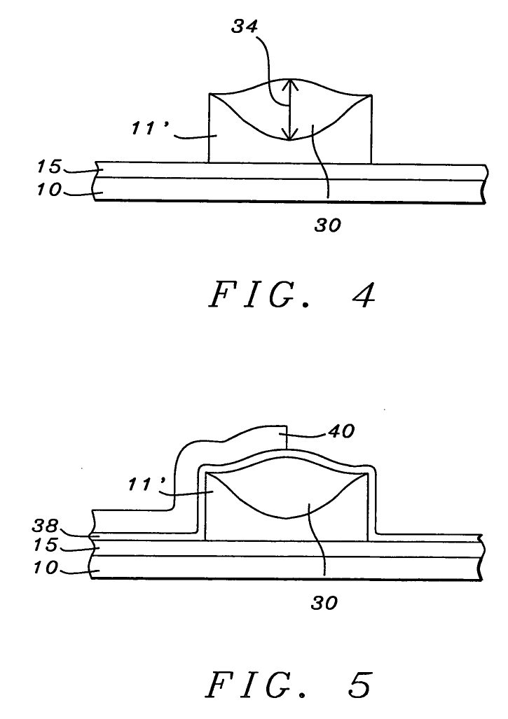

Further processing may then proceed in forming a flash memory 50 such as shown in FIG. 4 through FIG. 5 with, for example: the removal of nitride layer 14 and the remainder of etched thin oxide layer 12″; the patterning and removal of polysilicon layer 11 not under floating gate oxide portion 30 to form remaining polysilicon layer 11′; the formation of an interpoly oxide layer 38 over the structure and the formation of control gate 40.

The inventors have determined that the flash forward tunneling voltage (FTV) performance of flash memory is improved from about 8.0 to 7.0 and more preferably from about 7.6 to 7.4 when the method of the present invention is used to form the floating gate oxide layer 30 employed in the flash memory. Similarly, the FTV is decreased preferably from about 7.0 to 6.0 and more preferably from about 6.6 to 6.4 in such a flash memory.

While particular embodiments of the present invention have been illustrated and described, it is not intended to limit the invention, except as defined by the following claims.

We claim:

1. A FLASH memory device comprising a substrate having a gate conductor formed thereover, said gate conductor comprising a floating gate with a floating gate oxide layer formed thereon, said floating gate oxide layer including respective lateral tip portions, whereby the forward tunneling voltage of the FLASH memory is improved, said respective tip portions having an average width of greater than or equal to about 250 Å.

2. The FLASH memory device of claim 1, wherein said substrate defines a horizontal plane, and wherein said lateral tip portions each have an upper surface and lower surface opposite said upper surface, said upper surface beings substantially parallel to said horizontal plane along said average width.

3. The FLASH memory device of claim 1, wherein said floating gate oxide layer is formed by oxidizing said gate conductor.

4. The FLASH memory device of claim 3, wherein said gate conductor comprises polysilicon.

5. The FLASH memory device of claim 4, wherein said gate oxide layer has a mid-thickness of from about 1000-2000 Å.

6. The FLASH memory device of claim 1, further comprising a control gate formed over said floating gate oxide layer.

7. The FLASH memory device of claim 6, further comprising a gate oxide layer formed between said substrate and said gate conductor and an interlayer oxide formed between said control gate and said floating gate oxide.

8. The FLASH memory device of claim 1, wherein said respective tip portions have an average width of between about 250-350 Å.

9. The FLASH memory device of claim 1, wherein said respective tip portions have an average width of between about 280-320 Å.

10. A FLASH memory device formed according to the method comprising the following steps:
providing a structure having a conductor layer formed thereover;
forming a first layer over the conductor layer;
forming a second layer over the first layer;
patterning the second layer to form an opening exposing a portion of the first layer;
exposing a portion of the conductor layer by removing:
the exposed portion of the first layer; and
portions of the first layer underneath the patterned second layer adjacent to the opening to form respective undercuts; and
oxidizing the exposed portion of the conductor layer to form a floating gate oxide layer including respective tip corners, whereby the forward tunneling voltage of the FLASH memory is improved.

11. The FLASH memory device of claim 10, wherein each of the tip corners has an average width of greater than or equal to about 250 Å.

12. The FLASH memory device of claim 11, wherein the floating gate oxide layer has a mid-thickness of from about 1000-2000 Å.

13. The FLASH memory device of claim 10, wherein said conductor layer comprises polysilicon.

14. The FLASH memory device of claim 10, wherein the first layer comprises an oxide, and the exposed portion of the first layer and the portions of the first layer underneath the patterned second layer adjacent to the openings are removed by an oxide wet bench dip etching process.

15. The FLASH memory device of 14, wherein the undercuts extend from about 30-70 Å underneath the patterned second layer.

16. The FLASH memory device of claim 10, wherein the formation method further comprises:
removing remaining portions of said first and second layers; and
completing said FLASH memory device.

17. A FLASH memory device comprising a substrate having a gate conductor formed thereover, said gate conductor comprising a polysilicon floating gate with an oxidized region comprising a floating gate oxide layer formed thereon, said floating gate oxide layer including respective lateral tip portions, whereby the forward tunneling voltage of the FLASH memory is improved, wherein said substrate defines a horizontal plane, and wherein said lateral tip portions each have an upper surface and a lower surface opposite said upper surface, said upper surface being substantially parallel to said horizontal plane along the width of said lateral tip portions.

18. The FLASH memory device of claim 17, wherein said respective lateral tip portions have an average width of greater than or equal to about 250 Å.

19. The FLASH memory device of claim 18, further comprising:
a control gate formed over said floating gate oxide layer;
a gate oxide layer formed between said substrate and said gate conductor;
an interlayer oxide formed between the control gate and said floating gate oxide, wherein said gate oxide layer has a mid-thickness of from about 1000-2000 Å.

20. A FLASH memory device comprising a substrate having a gate conductor formed thereover, said gate conductor comprising a floating gate with a floating gate oxide layer formed thereon, said floating gate oxide layer including respective lateral tip portions, whereby the forward tunneling voltage of the FLASH memory is improved, wherein said respective tip portions have an average width TW and wherein CD is the critical dimension size which can be imaged by a selected photolithography process used in forming said FLASH memory device, wherein said FLASH memory device conforms to the following ratio: (2TW+CD)/CD is between or about 1.13-1.19.
